(19) United States
(12) Patent Application Publication
(10) Pub. No.: US 2016/0130693 A1
(43) Pub. Date: May 12, 2016

(54) METHOD OF MANUFACTURING MAGNETORESISTIVE MEMORY DEVICE AND MANUFACTURING APPARATUS OF THE SAME

(71) Applicants: Kazuya SAWADA, Seoul (KR); Toshihiko NAGASE, Seoul (KR); Youngmin EEH, Seoul (KR); Koji UEDA, Seoul (KR); Daisuke WATANABE, Seoul (KR); Makoto NAGAMINE, Seoul (KR)

(72) Inventors: Kazuya SAWADA, Seoul (KR); Toshihiko NAGASE, Seoul (KR); Youngmin EEH, Seoul (KR); Koji UEDA, Seoul (KR); Daisuke WATANABE, Seoul (KR); Makoto NAGAMINE, Seoul (KR)

(21) Appl. No.: 14/645,254

(22) Filed: Mar. 11, 2015

Related U.S. Application Data
(60) Provisional application No. 62/078,258, filed on Nov. 11, 2014.

(51) Int. Cl. C23C 14/02; H01L 43/08; H01L 43/12; C23C 14/08; C23C 14/54; C23C 14/56; C23C 14/06; H01L 43/02; C23C 14/34

(52) U.S. Cl. CPC C23C 14/02; H01L 43/02; H01L 43/08; H01L 43/12; C23C 14/3407; C23C 14/541; C23C 14/568; C23C 14/0647; C23C 14/0652; C23C 14/0641; C23C 14/0617; C23C 14/081; C23C 14/086; C23C 14/087; C23C 14/083; C23C 14/082; C23C 14/08

(57) ABSTRACT

According to one embodiment, a method of manufacturing a magnetoresistive memory device includes forming a first magnetic layer on a substrate, forming a cap layer on the first magnetic layer, heating a base including the cap layer after the cap layer is formed, forming a nonmagnetic layer on the cap layer while the base is heated, cooling the base including the nonmagnetic layer after the nonmagnetic layer is formed, and forming a second magnetic layer on the nonmagnetic layer after the base is cooled.

### CROSS-REFERENCE TO RELATED APPLICATIONS

This application claims the benefit of U.S. Provisional Application No. 62/078,258, filed Nov. 11, 2014, the entire contents of which are incorporated herein by reference.

### FIELD

Embodiments described herein relate generally to a method of manufacturing a magnetoresistive memory device and a manufacturing apparatus of the same.

### BACKGROUND

Recently, a large-capacity magnetoresistive random access memory (MRAM) using magnetic tunnel junction (MTJ) elements has been expected and attracted attention. In an MTJ element, one of the two magnetic layers that sandwich a tunnel barrier layer is set as a magnetization fixed layer (reference layer) where the direction of magnetization is fixed in order not to be changed, and the other layer is set as a magnetization free layer (storage layer) where the direction of magnetization is made to be easily inverted. Information can be stored by associating, with binary “0” and “1”, a state in which the direction of magnetization is parallel between the reference layer and the storage layer, and a state in which the direction of magnetization is anti-parallel between them.

The crystallinity of the tunnel barrier layer of MgO, etc., is improved by depositing the layer by heating a base substrate. However, this process causes aggregation and surface oxidation of the magnetic layers of CoFeB, etc., on the side of the base.

### BRIEF DESCRIPTION OF THE DRAWINGS

FIG. 1 is a block diagram showing a basic structure of a manufacturing apparatus of a magnetoresistive memory device according to a first embodiment.

FIGS. 2A to 2C are cross-sectional views showing schematic structures of a sputtering chamber used in the apparatus of FIG. 1.

FIG. 3 is a block diagram showing a modified example of the apparatus of FIG. 1.

FIG. 4 is a block diagram showing another modified example of the apparatus of FIG. 1.

FIGS. 5A to 5D are cross-sectional views showing a manufacturing process of the magnetoresistive memory device using the apparatus of FIG. 1.

FIG. 6 is a graph showing variation of a preset temperature of a heating mechanism in the process of FIGS. 5A to 5D.

FIG. 7 is a circuit configuration diagram showing a memory cell array of an MRAM according to a second embodiment.

FIG. 8 is a cross-sectional view showing a structure of a memory cell used in the MRAM of FIG. 7.

FIGS. 9A to 9E are cross-sectional views showing a manufacturing process of the memory cell of the MRAM according to the second embodiment.

### DETAILED DESCRIPTION

In general, according to one embodiment, a method of manufacturing a magnetoresistive memory device comprises: forming a first magnetic layer on a substrate; forming a cap layer on the first magnetic layer; heating a base including the cap layer after the cap layer is formed; forming a nonmagnetic layer on the cap layer while the base is heated; cooling the base including the nonmagnetic layer after the nonmagnetic layer is formed; and forming a second magnetic layer on the nonmagnetic layer after the base is cooled.

Various embodiments will be described hereinafter with reference to the accompanying drawings.

### First Embodiment

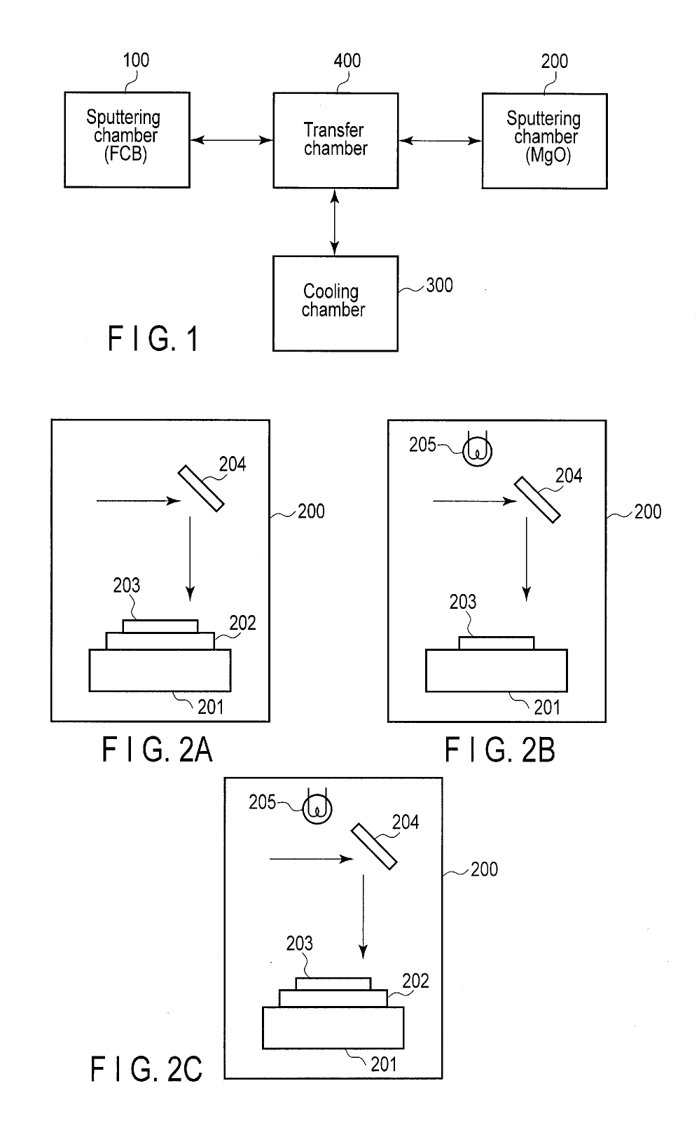

FIG. 1 is a block diagram showing a basic structure of a manufacturing apparatus of a magnetoresistive memory device according to a first embodiment.

A component represented by 100 in the drawings is a first sputtering chamber to form a first and second magnetic layers of CoFeB, etc., 200 is a second sputtering chamber to form a cap layer and a tunnel barrier layer (nonmagnetic layer) of MgO, etc., 300 is a cooling chamber to cool a substrate, and 400 is a transfer chamber to transfer the substrate between the chambers.

A stage on which the substrate is laid and a target of CoFeB are arranged in the first sputtering chamber 100. A CoFeB layer can be formed on the substrate by sputtering the target.

As shown in FIG. 2A, a stage 201 on which a substrate 203 is laid and a target 204 of MgO are arranged in the second sputtering chamber 200. An MgO layer can be formed on the substrate 203 by sputtering the target 204. A hotplate 202 is provided on the stage 201 of the chamber 200, which allows the substrate 203 to be heated from the underside before the MgO layer is deposited. The heating temperature of the hotplate 202 can be adjusted in two levels.

As shown in FIG. 2B, an infrared lamp 205 for infrared irradiation can be provided above in the chamber 200 instead of the hotplate 202 to execute lamp annealing for the upper surface of the substrate 203. As shown in FIG. 2C, both the hotplate 202 and the lamp 205 can be provided to heat the substrate 203 from both sides.

A stage on which the substrate is laid is arranged in the cooling chamber 300. Furthermore, coolant gas such as Ar can be introduced in the cooling chamber 300.

The cap layer and the barrier layer of MgO are formed in the sputtering chamber 200 in FIG. 1.

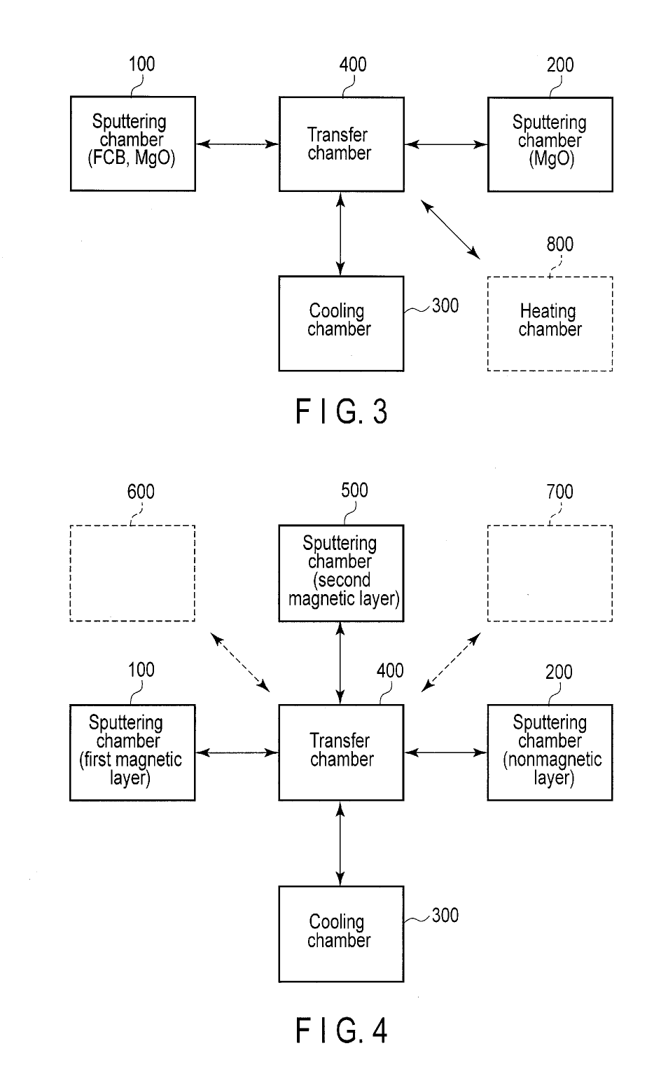

However, the magnetic layer of CoFeB and the cap layer of MgO may be formed in the sputtering chamber 100 and the MgO layer may be deposited by heating in the sputtering chamber 200 as shown in FIG. 3. In this case, an MgO target is provided along with the CoFeB target in the sputtering chamber 100. A sputtering chamber for forming the cap layer may be newly provided.

In addition, a heating chamber 800 to heat the substrate on which the cap layer is formed may be newly provided. In this case, since the substrate does not need to be heated in the sputtering chamber 200, a general chamber can be used as the sputtering chamber 200. The heating chamber can heat the substrate not only after the cap layer is formed, but also before the cap layer is formed.

As shown in FIG. 4, a third sputtering chamber 500 to form the second magnetic layer may be provided independently of the first sputtering chamber 100 to form the first magnetic layer, in order to form the first and second magnetic layers in different chambers. Besides the above, a fourth sputtering chamber 600 to form a base layer, a fifth sputtering chamber 700 to form a shift adjustment layer, etc., may be further provided.

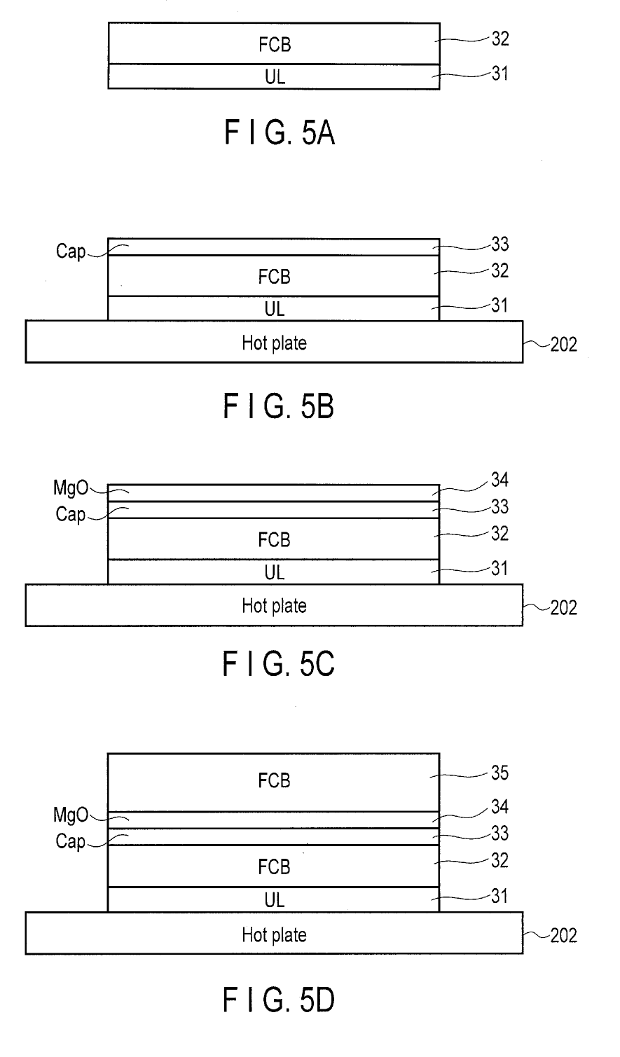

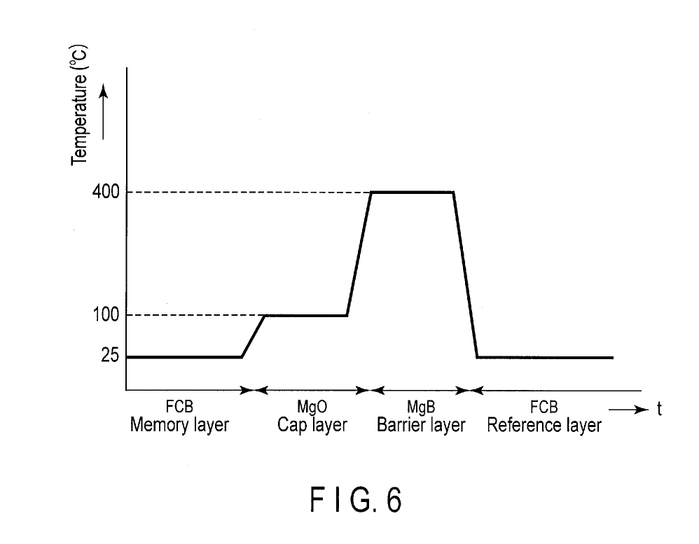

Next, a method of manufacturing the magnetoresistive memory device using the apparatus of FIG. 1 is described with reference to FIGS. 5A to 5D. FIG. 6 shows variation of the preset temperature of a heating mechanism during manufacture. When the hotplate 202 is used as the heating mechanism, variation of the substrate temperature follows the variation of the preset temperature of the heating mechanism with some delay. When the lamp 205 is used, the variation of the substrate temperature follows the variation of the preset temperature of the heating mechanism with very little delay. In each case, the substrate temperature follows the preset temperature of the heating mechanism. Therefore, the preset temperature of the heating mechanism can be substantially regarded as the substrate temperature.

In FIGS. 5A to 5D, the substrate is omitted to simplify the drawings. The sputtering chamber 200 is assumed to comprise the hotplate 202 as shown in FIG. 2A. It is also assumed that the substrate is transferred between the sputtering chambers 100 to 300 by the transfer chamber 400.

First, the substrate is transferred to the first sputtering chamber 100 and a first magnetic layer 32 is formed on the substrate via a base layer 31 as shown in FIG. 5A. At this time, the temperature is, for example, room temperature. The substrate is prepared by forming a bottom electrode of Ta, etc., on the semiconductor substrate. The base layer 31 and the magnetic layer 32 are formed to cover the bottom electrode. The base layer 31 aims to improve the crystallinity of a layer formed thereon. The magnetic layer 32 is used as a memory layer (or a reference layer) of an MTJ element and is, for example, CoFeB.

Next, the substrate in the sputtering chamber 100 is transferred to the second sputtering chamber 200, and then a cap layer 33 of MgO is formed on the magnetic layer 32 as shown in FIG. 5B. That is, the cap layer 33 of MgO, etc., is formed on the magnetic layer 32 by sputtering while the substrate is heated by the hotplate 202. A first heating temperature at this time is approximately 100° C., which does not cause aggregation of CoFeB of the base. The heating temperature of the substrate is not limited to 100° C., but may be equal to or lower than 200° C. which does not cause aggregation of CoFeB serving as the magnetic layer 32.

Next, the substrate is further heated by the hotplate 202 and then a tunnel barrier layer (nonmagnetic layer) 34 of MgO, etc., is formed on the cap layer 33 by sputtering as shown in FIG. 5C. A second heating temperature at this time is approximately 400° C., which is higher than the first heating temperature. Since the cap layer 33 has been already formed, the magnetic layer 32 remains flat without aggregation and surface oxidation even if the substrate is heated to 400° C. Crystallinity of the tunnel barrier layer 34 is therefore preferable. The temperature of the substrate is raised up to 400° C. by heating of the hotplate 202 before the tunnel barrier layer 34 is formed. During the formation of the tunnel barrier layer 34, the heating may be continued or stopped. Even if the heating is stopped, the temperature is sufficiently maintained during a formation time of the tunnel barrier layer 34 of several dozen seconds.

When a heating chamber is newly provided, the substrate may be heated to approximately 450° C. in the heating chamber after the cap layer 33 is deposited, and then the tunnel barrier layer 34 may be deposited. In this case, since a time from the heating in the heating chamber to the start of deposition of the tunnel barrier layer 34 is several dozen seconds, the temperature at the time of formation of the tunnel barrier layer 34 is maintained up to approximately 350° C. even if the heating is not executed by the hotplate 202.

Next, the substrate is transferred to the cooling chamber 300 and then cooled to room temperature by Ar gas.

Next, the substrate is transferred to the first sputtering chamber 100, and then a second magnetic layer 35 of CoFeB is formed on the tunnel barrier layer 34 as shown in FIG. 5D. Similarly to the magnetic layer 32, the magnetic layer 35 is used as a reference layer (or a memory layer) of the MTJ element and is, for example, CoFeB. The MTJ element in which the nonmagnetic layer 34 is sandwiched between the magnetic layers 32 and 35 can thereby be obtained.

The first magnetic layer 42 is a memory layer and the second magnetic layer 35 is a reference layer in the above example, but, of course, the first magnetic layer 42 may be a reference layer and the second magnetic layer 35 may be a memory layer.

As described above, according to the present embodiment, the crystallinity of the tunnel barrier layer 34 can be improved since the tunnel barrier layer 34 of MgO, etc., is formed while the base substrate is heated in a state where the cap layer 33 is formed on the magnetic layer 32 of CoFeB, etc. That is, the crystallinity of the tunnel barrier layer 34 can be improved since the tunnel barrier layer 34 can be formed at high temperature without causing aggregation of the magnetic layer 32 on the base side. Therefore, improvement of element characteristics of the MTJ element (for example, expansion of an MR ratio) can be achieved.

In the present embodiment, since the substrate is slightly heated when the cap layer 33 is formed, deterioration of the crystallinity of the cap layer 33 which occurs when the cap layer 33 is formed at low temperature 33 can also be inhibited. When the cap layer 33 is formed not in the second sputtering chamber 200 but in the first sputtering chamber 100, the cap layer 33 is formed at room temperature as in the case of forming the base magnetic layer 32. In contrast, the cap layer 33 can be deposited while being heated to approximately 100° C. by forming the cap layer 33 in the sputtering chamber 200 as in the apparatus of FIG. 1. The crystallinity of the tunnel barrier layer 34 can thereby be further improved.

If annealing is executed by the lamp 205 instead of the hotplate 202 in the second sputtering chamber 200, the temperature setting in the formation of the cap layer and the temperature setting in the formation of the barrier layer can be immediately switched. Productivity can thereby be improved. Since the substrate is heated from the upper side in the lamp annealing, the temperature of the upper surface of the cap layer 33 can be higher than that on the side of the substrate in comparison with the case of heating the substrate from the underside such as a case of using the hotplate. Accordingly, the growing surface can be heated to higher temperature without causing aggregation and surface oxidation of the base magnetic layer 32. Therefore, the crystallinity of the tunnel barrier layer 34 can thereby be further improved.

### Second Embodiment

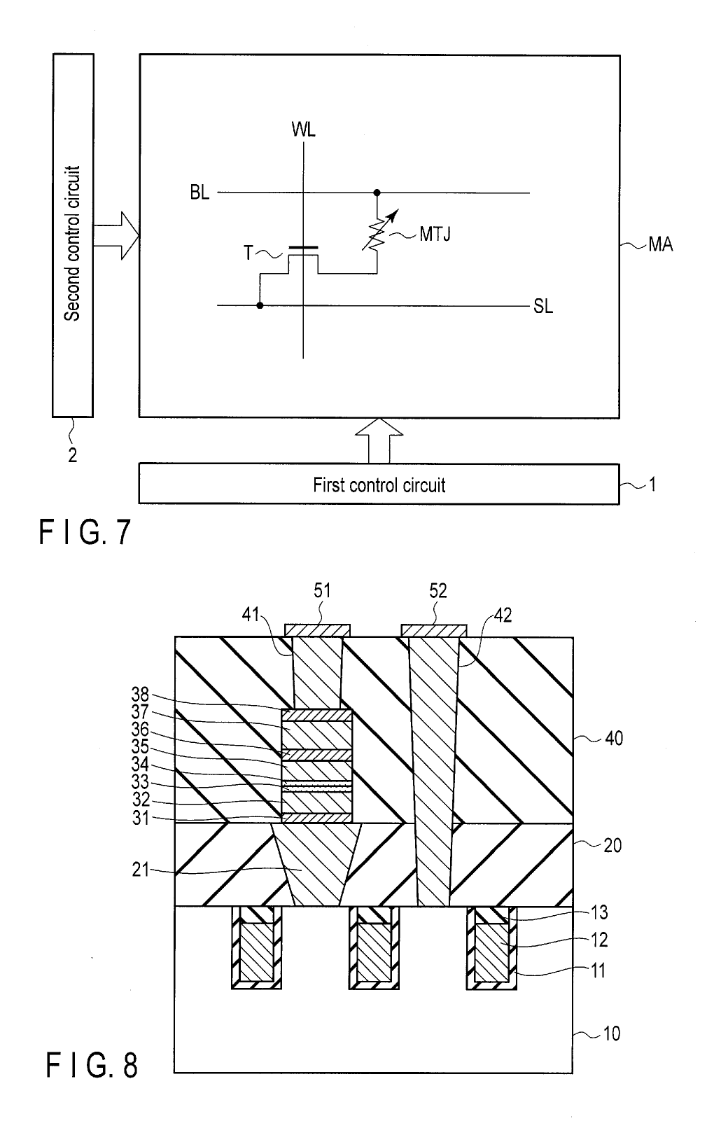

FIG. 7 is a circuit configuration diagram showing a memory cell array of an MRAM of a second embodiment.

A memory cell in a memory cell array MA comprises a series-connected body of an MTJ element serving as a magnetic memory element and a switching element (for example, a field-effect transistor [FET]) T. One end of the series-connected body (one end of the MTJ element) is electrically connected to a bit line BL. The other end of the series-connected body (one end of the switching element T) is electrically connected to a source line SL.

A control terminal of the switching element T, for example, a gate electrode of the FET is electrically connected to a word line WL. The potential of the word line WL is controlled by a first control circuit 1.

The potential of the bit line BL and the potential of the source line SL are controlled by a second control circuit 2.

FIG. 8 is a cross-sectional view showing a structure of the memory cell used in the MRAM of the second embodiment.

An MOS transistor for switching is formed on an upper surface of an Si substrate 10, and an interlayer insulating film 20 of SiO₂, etc., is formed thereon. The transistor has a buried gate structure obtained by burying a gate electrode 12 in a groove provided on the substrate 10 via a gate insulating film 11. The gate electrode 12 is partially buried in the groove and a protective insulating film 13 of SiN, etc., is formed thereon. A source-drain region (not shown) is formed by diffusing p- or n-type impurities on the substrate 10 on both sides of the buried gate structure.

The structure of the transistor is not limited to the buried gate structure. For example, the structure may be obtained by forming a gate electrode on the upper surface of the Si substrate 10 via a gate insulating film. The transistor may have any structure that functions as a switching element.

A contact hole to be connected to a drain of the transistor is formed on the interlayer insulating film 20, and a bottom electrode (BEC) 21 is buried in the contact hole. The bottom electrode 21 is, for example, Ta.

A base layer 31 is formed on a part of the bottom electrode 21. The base layer 31 aims to improve the crystallinity of a layer formed thereon.

A memory layer (first magnetic layer: SL) 32 which is a ferromagnetic magnetization free layer of CoFeB, a cap layer 33 of MgO, a tunnel barrier layer (inner layer: IL) 34 of MgO, a reference layer (second magnetic layer: RL) 35 which is a ferromagnetic magnetization fixed layer of CoFeB, an inner layer 36 of Ru, etc., a shift adjustment layer 37 of CoPt, etc., and a cap layer 38 of Ta, Ru, etc., are formed on the base layer 31. That is, an MTJ element 30 is structured by sandwiching the tunnel barrier layer 34 between the two ferromagnetic layers 32 and 35, and the shift adjustment layer 37 is formed above the MTJ element 30. The base layer 31 and the inner layer 36 aim to accelerate crystallization of layers formed thereon and can be omitted.

The memory layer 32 may preferably be of a material having magnetic crystal anisotropy (for example, CoPd) or a material having magnetic interface anisotropy such as CFB (CoFeB) oxide. The same holds true for a material of the reference layer 34.

An interlayer insulating film 40 of SiO₂, etc., is formed on the substrate on which the MTJ element 30 is formed. A contact plug (TEC) 41 connected to the cap layer 38 on the MTJ element 30 is buried in the interlayer insulating film 40. A contact plug 42 connected to the source of the transistor is buried by penetrating the interlayer insulating film 40 and the interlayer insulating film 20. A line (BL) 51 connected to the contact plug 41 and a line (SL) 52 connected to the contact plug 42 are formed on the interlayer insulating film 40.

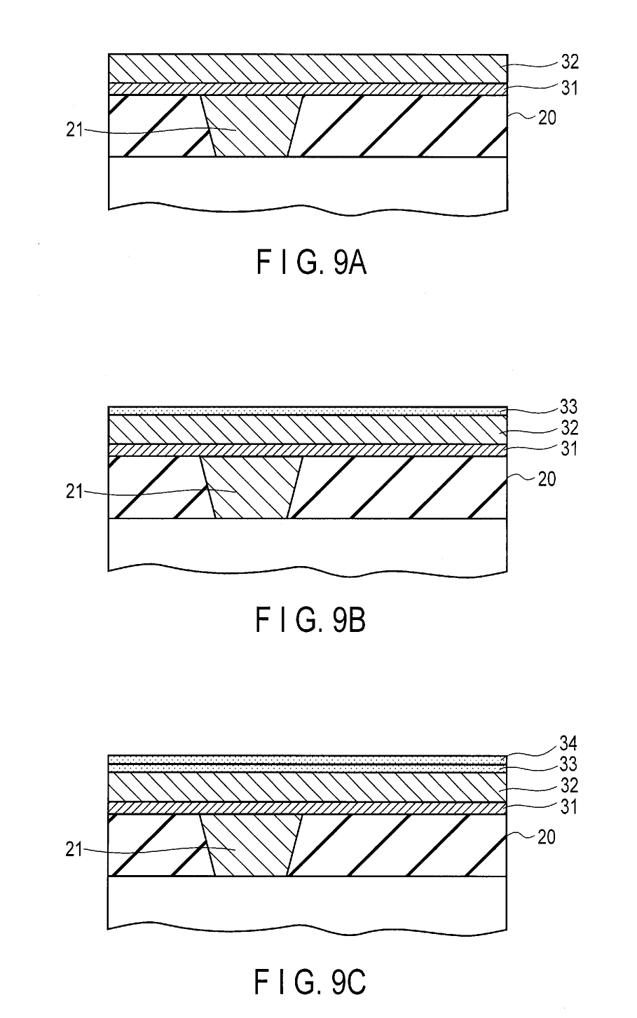

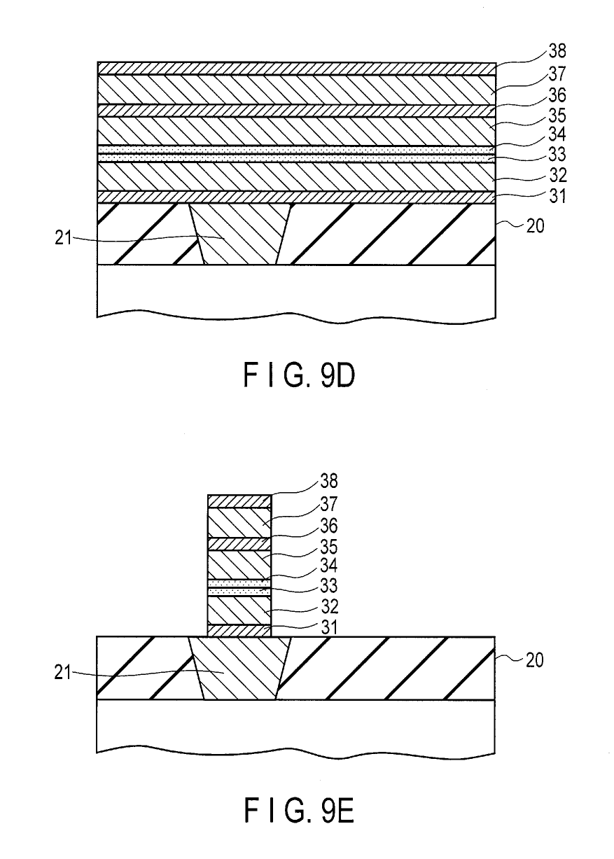

Next, a method of manufacturing the memory cell of FIG. 8 is described with reference to FIGS. 9A to 9E.

These drawings show layers from the bottom electrode 21 to the cap layer 38 to simplify the description. A manufacturing apparatus used at this time is the same as the apparatus of FIG. 1.

First, the memory layer 32 is formed on the base substrate via the base layer 31 as shown in FIG. 9A. That is, the base layer 31 is formed on the bottom electrode 21 and the interlayer insulating film 20, and then the memory layer 32 of CoFeB, etc., is formed by sputtering.

The base substrate is formed as follows. For example, the MOS transistor (not shown) for switching having the buried gate structure on the upper surface of the Si substrate 10 is formed, and then the interlayer insulating film 20 of SiO₂, etc., is deposited on the Si substrate 10 by the CVD method. Next, the contact hole to be connected to the drain of the transistor is formed on the interlayer insulating film 20, and then the bottom electrode (BEC) 21 made of crystalline Ta is buried in the contact hole. Next, a Ta film is left only in the contact hole by removing the Ta film on the interlayer insulating film 20 by chemical mechanical polishing (CMP).

Next, the cap layer 33 of MgO is formed on the memory layer 32 by sputtering as shown in FIG. 9B. The cap layer 33 may be formed at room temperature similarly to the magnetic layer 32, or formed after the base substrate is preheated to approximately 100° C.

Next, the tunnel barrier layer 34 of MgO is formed on the cap layer 33 as shown in FIG. 9C. Before the tunnel barrier layer 34 is formed, the base substrate is preheated to approximately 400° C. The crystallinity of the tunnel barrier layer 34 can thereby be improved.

Next, after the base substrate on which the tunnel barrier layer 34 is formed is cooled to approximately room temperature, the reference layer 35 of CoFeB, etc., is formed on the tunnel barrier layer 34, and the inner layer 36, the shift adjustment layer 37 and the cap layer 38 are further formed thereon as shown in FIG. 9D.

Next, a hard mask (not shown) is formed on the cap layer 38, and then the layers from the cap layer 38 to the base layer 31 are selectively etched in an element pattern to reach the bottom electrode 21 by, for example, ion beam etching (IBE) using Ar as shown in FIG. 9E.

Then, the structure shown in FIG. 8 can be obtained by forming the interlayer insulating film 40, forming the contact plugs 41 and 42, and further forming the lines 51 and 52.

As described above, in the present embodiment, too, the crystallinity of the tunnel barrier layer 34 can be improved since the tunnel barrier layer 34 of MgO, etc., is formed while the base substrate is heated in a state where the cap layer 33 is formed on the memory layer 32 of CoFeB, etc. Therefore, the same effect as the first embodiment can be achieved.

### Modified Embodiments

The present invention is not limited to each of the above-described embodiments.

The base substrate is heated when the cap layer and the nonmagnetic layer are formed in the embodiments, but the process is not limited to this. A present embodiment is characterized in that a base substrate is heated when a nonmagnetic layer serving as a tunnel barrier is formed, and the substrate is not necessarily heated when the cap layer is formed.

As the tunnel barrier layer and the cap layer, not only MgO, but also oxide or nitride including at least one of Si, Ba, Ca, La, Mn, Zn, Hf, Ta, Ti, B, Cu, Cr, V, Mg, Al, etc., can be used. Specifically, when a perpendicular magnetic memory is manufactured, a material that induces magnetic anisotropy on a boundary face with the magnetic layer is preferable. If such materials are used, excellent crystals of the nonmagnetic layer can also be obtained by forming the nonmagnetic layer while heating the base substrate in a state where the cap layer is formed.

The cap layer and the tunnel barrier layer are of the same material in the embodiments, but these layers are not necessarily of the same material. As the cap layer, any material that does not produce aggregation at high temperature in the formation of the nonmagnetic layer and accelerates the crystallization of the nonmagnetic layer can be used. If the cap layer and the nonmagnetic layer are of different materials, the cap layer may be formed in a chamber other than the second sputtering chamber.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetoresistive memory device, the method comprising:
forming a first magnetic layer on a substrate;
forming a cap layer on the first magnetic layer;
heating a base including the cap layer at a first temperature after the cap layer is formed;
forming a nonmagnetic layer on the cap layer; and
forming a second magnetic layer on the nonmagnetic layer.

2. The method of claim 1, wherein
the heating the base is heating the substrate by a hotplate on which the substrate is laid.

3. The method of claim 1, wherein
the heating the base is emitting infrared radiation toward the cap layer.

4. The method of claim 1, further comprising:
heating the base including the first magnetic layer at a second temperature lower than the first temperature before the cap layer is formed.

5. The method of claim 1, wherein
the cap layer and the nonmagnetic layer are formed by sputtering in a same chamber.

6. The method of claim 1, wherein
the cap layer is nonmagnetic.

7. The method of claim 5, wherein
the cap layer and the nonmagnetic layer are of a same material.

8. The method of claim 1, wherein
one of the first and second magnetic layers is a storage layer and other one of the layers is a reference layer, and
the nonmagnetic layer is a tunnel barrier layer.

9. The method of claim 1, wherein
the cap layer is oxide or nitride including at least one of Si, Ba, Ca, La, Mn, Zn, Hf, Ta, Ti, B, Cu, Cr, V, Mg, and Al.

10. The method of claim 1, wherein
the base including the nonmagnetic layer is cooled after the nonmagnetic layer is formed and before the second magnetic layer is formed.

11. The method of claim 1, wherein
the heating at the first temperature is continued while the nonmagnetic layer is formed.

12. The method of claim 4, wherein
the heating at the second temperature is continued while the cap layer is formed.

13. The method of claim 4, wherein
the second temperature is equal to or lower than 200° C.

14. A manufacturing apparatus of a magnetoresistive memory device, the apparatus comprising:
a first sputtering chamber to form a first magnetic layer on a substrate;
a second sputtering chamber to sequentially form a cap layer and a nonmagnetic layer on the first magnetic layer, the second sputtering chamber comprising a heating mechanism; and
a transfer chamber to transfer the substrate between the chambers.

15. The apparatus of claim 14, further comprising:
a cooling chamber to cool the substrate on which the cap layer and the nonmagnetic layer are formed.

16. The apparatus of claim 14, wherein
the heating mechanism is a hotplate provided on a side of a stage on which the substrate is laid.

17. The apparatus of claim 14, wherein
the heating mechanism is a lamp which emits infrared radiation.

18. The apparatus of claim 14, wherein
the heating mechanism heats the substrate on which the first magnetic layer and the cap layer are formed.

19. The apparatus of claim 14, wherein
the heating mechanism is configured to set a first temperature at which the cap layer is formed and a second temperature at which the nonmagnetic layer is formed to be different from each other, and
the second temperature is higher than the first temperature.

20. The apparatus of claim 15, wherein
the first sputtering chamber is configured to form a second magnetic layer on the nonmagnetic layer on the substrate cooled by the cooling chamber.

21. The apparatus of claim 15, further comprising:
a third sputtering chamber to form the second magnetic layer on the nonmagnetic layer on the substrate cooled by the cooling chamber.

22. A manufacturing apparatus of a magnetoresistive memory device, the apparatus comprising:
a sputtering chamber to form a magnetic layer and a nonmagnetic layer on a substrate;
a heating chamber to heat the substrate; and
a transfer chamber to transfer the substrate between the chambers.

23. The apparatus of claim 22, further comprising:
a cooling chamber to cool the substrate.
